(19) United States
(12) Patent Application Publication
(10) Pub. No.: US 2025/0355154 A1
(43) Pub. Date: Nov. 20, 2025

(54) SYSTEMS AND METHODS OF ON-CHIP POLARIZATION ROUTING IN IMAGE SENSORS

(71) Applicant: Samsung Electronics Co., Ltd., Suwon-si (KR)

(72) Inventors: Radwanul Hasan SIDDIQUE, Monrovia, CA (US); Mahsa TORFEH, Los Angeles, CA (US); Haeri Park HANANIA, Sierra Madre, CA (US)

(21) Appl. No.: 19/046,508

(22) Filed: Feb. 5, 2025

Related U.S. Application Data
(60) Provisional application No. 63/647,610, filed on May 14, 2024.

(51) Int. Cl. G02B 5/30; G01J 4/04; H10F 39/00

(52) U.S. Cl. CPC G02B 5/3058; G01J 4/04; H10F 39/8063

(57) ABSTRACT

Provided are systems, methods, and apparatuses for routing polarization states of light towards a photodetector of a polarization sensor. In one or more examples, the systems, devices, and methods include routing a first polarization of light to a first wire grid of a wire grid array; routing a second polarization of light different from the first polarization of light to a second wire grid of the wire grid array; and filtering, via the wire grid array, the first polarization of light and the second polarization of light to sensor pixels of the photodetector.

### CROSS-REFERENCE TO RELATED APPLICATION

This application claims the priority benefit under 35 U.S.C. § 119 (e) of U.S. Provisional Patent Application Ser. No. 63/647,610, filed May 14, 2024, the disclosure of which is incorporated by reference in its entirety as if fully set forth herein.

### TECHNICAL FIELD

The disclosure generally relates generally to memory systems. More particularly, the subject matter disclosed herein relates to improvements to image sensors or polarization sensors with on-chip polarization routing.

### SUMMARY

Polarization can include a property of light which shows the direction of vibration for electromagnetic fields. Using polarizers and/or filters, electromagnetic vibrations can be directed in a given direction or towards a given location.

A polarization sensor can include an image sensor configured to detect the polarization of light, meaning it can measure the direction in which light waves are oscillating. Polarization sensors can provide information about a surface's properties that may not be detectable by a camera in the visual-spectrum, such as stress levels in a material or the orientation of reflective surfaces. Polarization image sensors can reliably identify differences in the degree of polarization between uneven areas, accurately perceiving scratches with a specific direction and detecting them while distinguishing them from stains which have random irregularities. Polarization sensors can capture the polarization angle of light beyond its intensity and color, making polarization sensors useful in applications such as industrial inspection, scientific research, medical sensors, etc.

Polarization can be based on a property of light that shows the direction of vibration for electromagnetic fields. Using polarizers/filters, the electromagnetic vibrations can be directed to a specific location. Some systems for detecting polarization states may use a different polarizer filter on top of an image sensor, which can reduce the unwanted polarization states, thereby reducing the optical signals. Some systems can route unwanted polarization light from other pixels to a target pixel to improve the light collection efficiency. However, such systems can increase crosstalk and can have a relatively low extinction ratio.

To overcome these issues, systems and methods are described herein for image sensors or polarization sensors with on-chip polarization routing. The systems and methods described can include coupling on-chip light routers and light filters to increase the signal collection, increase the signal-to-noise ratio, increase the extinction ratio, and reduce crosstalk. Crosstalk can refer to the unwanted signal interference, where light intended for a first photodetector (PD) pixel is detected by a second PD pixel, resulting in reduced signal quality. Extinction ratio may refer to the ratio of the electrical signal generated when a high optical power level is received (e.g., representing binary 1) compared to the signal generated when a low optical power level is received (e.g., representing binary 0), where a higher extinction ratio indicates a better distinction between the high and low levels.

The systems and methods described herein may provide a high-performance on-chip polarization sensor that combines polarization routing and filtering with full-Stokes detection capability (e.g., for machine vision, healthcare, etc.).

The systems and methods include multiple advantages. For example, the systems and methods described avoid the efficiency limit of 25% of some systems (e.g., of 2×2 polarization pixel systems). In some cases, the systems and methods add polarization routing capability of on-chip polarization sensors to increase signal collection. In some examples, the systems and methods described couple on-chip polarization routers and filters to improve the signal collection, increase the signal-to-noise ratio (SNR), improve the extinction ratio (ER), and/or reduce crosstalk.

The systems and methods described may include a polarization filter that may include wiregrids (e.g., wire grid array with metal and/or metal oxide layers). The polarization filter may induce phase modulation for polarization routing, focusing of incident light (e.g., based on metastructures with high index dielectrics). In some cases, the systems and methods may be based on one or more polarization filters with one or more microlenses. For example, a given system may include a 2×2 polarization filter and a microlens per 2×2 pixels. In some cases, the systems and methods described may include a 1×1 (singular) polarization filter or a 1×2 (bifurcated) polarization filter and a microlens per 2×2 pixels.

The above approaches improve on previous methods because the systems and methods described avoid the efficiency limit of some systems (e.g., 25% limit for 2×2 polarization pixel systems). In some cases, the systems and methods add polarization routing capability of on-chip polarization sensors to increase signal collection. In some examples, the systems and methods described couple on-chip polarization routers and filters, resulting in improved signal collection, an increased signal-to-noise ratio (SNR), improved extinction ratio (ER), and/or reduced crosstalk.

In some aspects, the techniques described herein relate to a polarization sensor including: a metastructure including two or more nanostructure patterns that are configured to route polarization states of light towards a photodetector of the polarization sensor, the two or more nanostructure patterns including: a first nanostructure pattern configured to route a first polarization of light to a first wire grid of a wire grid array, and a second nanostructure pattern configured to route a second polarization of light different from the first polarization of light to a second wire grid of the wire grid array; and the wire grid array configured to filter the first polarization of light and the second polarization of light to sensor pixels of the photodetector.

In some aspects, the techniques described herein relate to a polarization sensor, wherein: the first wire grid of the wire grid array is configured to allow the first polarization of light of a first wavelength to pass through to a first sensor pixels of the photodetector and reflect or absorb the second polarization of light away from the first sensor pixels, and the second wire grid of the wire grid array is configured to allow the second polarization of light of the first wavelength to pass through to a second sensor pixels of the photodetector and reflect or absorb the first polarization of light away from the second sensor pixels of the photodetector.

In some aspects, the techniques described herein relate to a polarization sensor, wherein: the first nanostructure pattern is configured to route a first wavelength of light to the first wire grid of the wire grid array, and the second nanostructure pattern is configured to route a second wavelength of light different from the first wavelength of light to the second wire grid of the wire grid array.

In some aspects, the techniques described herein relate to a polarization sensor, further including: a third nanostructure pattern of the metastructure configured to route a third polarization of light to a third wire grid of the wire grid array; and a fourth nanostructure pattern of the metastructure configured to route a fourth polarization of light different from the third polarization of light to a fourth wire grid of the wire grid array.

In some aspects, the techniques described herein relate to a polarization sensor, wherein: the third wire grid of the wire grid array is configured to allow the third polarization of light to pass through to a third sensor pixels of the photodetector and reflect or absorb the fourth polarization of light away from the third sensor pixels, and the fourth wire grid of the wire grid array is configured to allow the fourth polarization of light to pass through to a fourth sensor pixels of the photodetector and reflect or absorb the third polarization of light away from the fourth sensor pixels of the photodetector.

In some aspects, the techniques described herein relate to a polarization sensor, wherein: the first nanostructure pattern includes N nanostructure elements that repeat at least one time in the metastructure, and the second nanostructure pattern includes M nanostructure elements that repeat at least one time in the metastructure, the M nanostructure elements being less, more, or same in number as the N nanostructure elements.

In some aspects, the techniques described herein relate to a polarization sensor, wherein: a first nanostructure element of the N nanostructure elements varies in phase from a second nanostructure element of the N nanostructure elements, and the variation in phase is based on a quotient of Pi and N.

In some aspects, the techniques described herein relate to a polarization sensor, wherein: a width of a first nanostructure element of a repeating set of nanostructure elements of the metastructure does not match a length of the first nanostructure element, a rotational orientation of the first nanostructure element matches a rotational orientation of a second nanostructure element of the repeating set of nanostructure elements, or a rotational orientation of a third nanostructure element of the repeating set of nanostructure elements does not match a rotational orientation of a fourth nanostructure element of the repeating set of nanostructure elements.

In some aspects, the techniques described herein relate to a polarization sensor, wherein: a width of the third nanostructure element does not match the width of the fourth nanostructure element, or a length of the third nanostructure element does not match the length of the fourth nanostructure element.

In some aspects, the techniques described herein relate to a polarization sensor, wherein: a width of a fifth nanostructure element of the metastructure matches the width of a sixth nanostructure element of the metastructure, and a length of the fifth nanostructure element of the metastructure matches the length of the sixth nanostructure element of the metastructure.

In some aspects, the techniques described herein relate to a polarization sensor, wherein light passes through at least one of a global lens, a microlens, or an anti-reflective layer of the polarization sensor to reach the metastructure.

In some aspects, the techniques described herein relate to a polarization sensor, wherein the polarization sensor includes a capping layer between the metastructure and the wire grid array, the wire grid array being adjacent to the photodetector, and the capping layer including a refractive index equal to or less than 3.

In some aspects, the techniques described herein relate to a polarization sensor, wherein the first polarization of light or the second polarization of light include a horizontal polarization, a vertical polarization, a diagonal polarization, an anti-diagonal polarization, a right-handed circular polarization, or a left-handed circular polarization.

In some aspects, the techniques described herein relate to a polarization sensor, wherein the metastructure includes at least one layer of nanostructure elements, at least one of the layers including a relatively high index dielectric.

In some aspects, the techniques described herein relate to a polarization sensor, wherein the wire grid array includes at least one of an array of metal wires and a substrate.

In some aspects, the techniques described herein relate to a system including: at least one polarization sensor, the at least one polarization sensor including: a metastructure including two or more nanostructure patterns that are configured to route polarization states of light towards a photodetector of the polarization sensor, the two or more nanostructure patterns including: a first nanostructure pattern configured to route a first polarization of light to a first wire grid of a wire grid array, and a second nanostructure pattern configured to route a second polarization of light different from the first polarization of light to a second wire grid of the wire grid array; and the wire grid array configured to filter the first polarization of light and the second polarization of light to sensor pixels of the photodetector.

In some aspects, the techniques described herein relate to a system, wherein: the first wire grid of the wire grid array is configured to allow the first polarization of light of a first wavelength to pass through to a first sensor pixels of the photodetector and reflect the second polarization of light away from the first sensor pixels, and the second wire grid of the wire grid array is configured to allow the second polarization of light of the first wavelength to pass through to a second sensor pixels of the photodetector and reflect the first polarization of light away from the second sensor pixels of the photodetector.

In some aspects, the techniques described herein relate to a system, wherein: the first nanostructure pattern is configured to route a first wavelength of light to the first wire grid of the wire grid array, and the second nanostructure pattern is configured to route a second wavelength of light different from the first wavelength of light to the second wire grid of the wire grid array.

In some aspects, the techniques described herein relate to a method of routing polarization states of light towards a photodetector of a polarization sensor, the method including: routing, via a first nanostructure pattern of a metastructure, a first polarization of light to a first wire grid of a wire grid array; routing, via a second nanostructure pattern of the metastructure, a second polarization of light different from the first polarization of light to a second wire grid of the wire grid array; and filtering, via the wire grid array, the first polarization of light and the second polarization of light to sensor pixels of the photodetector.

In some aspects, the techniques described herein relate to a method, wherein: the first wire grid of the wire grid array is configured to allow the first polarization of light of a first wavelength to pass through to a first sensor pixels of the photodetector and reflect the second polarization of light away from the first sensor pixels, and the second wire grid of the wire grid array is configured to allow the second polarization of light of the first wavelength to pass through to a second sensor pixels of the photodetector and reflect the first polarization of light away from the second sensor pixels of the photodetector.

### BRIEF DESCRIPTION OF THE DRAWING

In the following section, the aspects of the subject matter disclosed herein will be described with reference to exemplary embodiments illustrated in the figures, in which:

FIG. 1 illustrates an example system in accordance with one or more implementations as described herein.

FIG. 2 illustrates an example system in accordance with one or more implementations as described herein.

FIG. 3 illustrates an example system in accordance with one or more implementations as described herein.

FIG. 4 illustrates an example metastructure in accordance with one or more implementations as described herein.

FIG. 5 illustrates an example system in accordance with one or more implementations as described herein.

FIG. 6 illustrates an example system in accordance with one or more implementations as described herein.

FIG. 7 illustrates an example metastructure in accordance with one or more implementations as described herein.

FIGS. 8-12 illustrate example patterns in accordance with one or more implementations as described herein.

FIG. 13 illustrates an example system in accordance with one or more implementations as described herein.

FIG. 14 depicts a flow diagram illustrating an example method associated with the disclosed systems, in accordance with example implementations described herein.

FIG. 15 depicts a flow diagram illustrating an example method associated with the disclosed systems, in accordance with example implementations described herein.

FIG. 16 depicts a flow diagram illustrating an example method associated with the disclosed systems, in accordance with example implementations described herein.

### DETAILED DESCRIPTION

In the following detailed description, numerous specific details are set forth in order to provide a thorough understanding of the disclosure. It will be understood, however, by those skilled in the art that the disclosed aspects may be practiced without these specific details. In other instances, well-known methods, procedures, components and circuits have not been described in detail to not obscure the subject matter disclosed herein.

Reference throughout this specification to “one embodiment” or “an embodiment” means that a particular feature, structure, or characteristic described in connection with the embodiment may be included in at least one embodiment disclosed herein. Thus, the appearances of the phrases “in one embodiment” or “in an embodiment” or “according to one embodiment” (or other phrases having similar import) in various places throughout this specification may not necessarily all be referring to the same embodiment. Furthermore, the particular features, structures or characteristics may be combined in any suitable manner in one or more embodiments. In this regard, as used herein, the word “exemplary” means “serving as an example, instance, or illustration.” Any embodiment described herein as “exemplary” is not to be construed as necessarily preferred or advantageous over other embodiments. Additionally, the particular features, structures, or characteristics may be combined in any suitable manner in one or more embodiments. Also, depending on the context of discussion herein, a singular term may include the corresponding plural forms and a plural term may include the corresponding singular form. Similarly, a hyphenated term (e.g., “two-dimensional,” “pre-determined,” “pixel-specific,” etc.) may be occasionally interchangeably used with a corresponding non-hyphenated version (e.g., “two dimensional,” “predetermined,” “pixel specific,” etc.), and a capitalized entry (e.g., “Counter Clock,” “Row Select,” “PIXOUT,” etc.) may be interchangeably used with a corresponding non-capitalized version (e.g., “counter clock,” “row select,” “pixout,” etc.). Such occasional interchangeable uses shall not be considered inconsistent with each other.

Also, depending on the context of discussion herein, a singular term may include the corresponding plural forms and a plural term may include the corresponding singular form. It is further noted that various figures (including component diagrams) shown and discussed herein are for illustrative purpose only, and are not drawn to scale. For example, the dimensions of some of the elements may be exaggerated relative to other elements for clarity. Further, if considered appropriate, reference numerals have been repeated among the figures to indicate corresponding and/or analogous elements.

The terminology used herein is for the purpose of describing some example embodiments only and is not intended to be limiting of the claimed subject matter. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that when an element or layer is referred to as being on, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

The terms “first,” “second,” etc., as used herein, are used as labels for nouns that they precede, and do not imply any type of ordering (e.g., spatial, temporal, logical, etc.) unless explicitly defined as such. Furthermore, the same reference numerals may be used across two or more figures to refer to parts, components, blocks, circuits, units, or modules having the same or similar functionality. Such usage is, however, for simplicity of illustration and case of discussion only; it does not imply that the construction or architectural details of such components or units are the same across all embodiments or such commonly-referenced parts/modules are the only way to implement some of the example embodiments disclosed herein.

Unless otherwise defined, all terms (including technical and scientific terms) used herein have the same meaning as commonly understood by one of ordinary skill in the art to which this subject matter belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, the term “module” refers to any combination of software, firmware and/or hardware configured to provide the functionality described herein in connection with a module. For example, software may be embodied as a software package, code and/or instruction set or instructions, and the term “hardware,” as used in any implementation described herein, may include, for example, singly or in any combination, an assembly, hardwired circuitry, programmable circuitry, state machine circuitry, and/or firmware that stores instructions executed by programmable circuitry. The modules may, collectively or individually, be embodied as circuitry that forms part of a larger system, for example, but not limited to, an integrated circuit (IC), system on-a-chip (SoC), an assembly, and so forth.

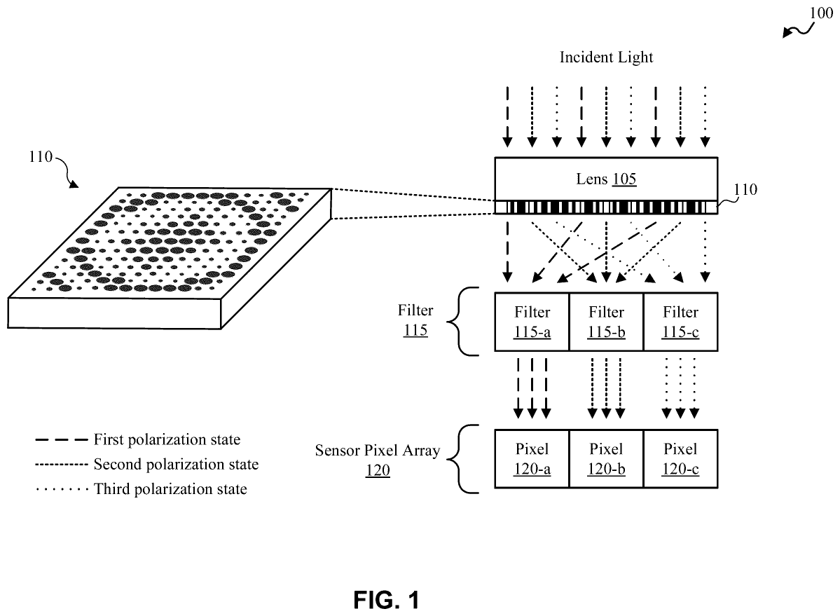

FIG. 1 illustrates an example system 100 in accordance with one or more implementations as described herein. In some configurations, one or more aspects of system 100 may be implemented by or in conjunction with a polarization sensor.

In the illustrated example, system 100 may include a lens 105, a metastructure 110 (e.g., light routing metastructure, polarization routing metastructure), a filter 115 (e.g., polarization filter), and one or more sensor pixels (e.g., sensor pixel array 120 of a photodetector). In some cases, lens 105 may include a global lens, one or more microlenses, and/or one or more anti-reflective layers (e.g., one or more anti-glare layers to reduce amount of light that reflects off of lens 105, allowing more light to pass through). In some examples, filter 115 may include one or more filter elements (e.g., filter 115-a, filter 115-b, filter 115-c). In the illustrated example, sensor pixels may include at least pixel 120-a, pixel 120-b, pixel 120-c.

In the illustrated example, light incident on system 100 may include one or more polarization states (e.g., a first polarization state, a second polarization state, a third polarization state, etc.). The incident light may pass through lens 105 to reach metastructure 110. Metastructure 110 may include one or more nanostructure elements. The one or more nanostructure elements of metastructure 110 may be configured to route and/or focus the light incident on lens 105. In some cases, metastructure 110 may route and/or focus the light based on one or more wavelengths of the light (e.g., one or more wavelength ranges) and/or one or more polarization states of the light. As shown, metastructure 110 may route and/or focus a first wavelength (e.g., first wavelength range) and/or a first polarization state of the incident light towards filter 115-a. In some examples, metastructure 110 may route and/or focus a second wavelength (e.g., second wavelength range) and/or a second polarization state of the incident light towards filter 115-b. In some cases, metastructure 110 may route and/or focus a third polarization state of the incident light towards filter 115-c. In some examples, metastructure 110 may route and/or focus a first polarization of light of a first wavelength (e.g., first wavelength range) towards filter 115-a, and may route and/or focus a second polarization of light of the first wavelength (e.g., first wavelength range) and/or a second wavelength (e.g., second wavelength range) towards filter 115-b. In some cases, metastructure 110 may route and/or focus a first polarization of light of one or more wavelengths (e.g., one or more wavelength ranges) towards filter 115-a. In some examples, metastructure 110 may route and/or focus a second polarization of light of one or more wavelength (e.g., one or more wavelength ranges) towards filter 115-b, where at least one wavelength (e.g., at least one wavelength range) of the first polarization of light may match at least one wavelength or overlap at least one wavelength range of the second polarization of light. In some cases, no wavelength or wavelength range of the first polarization of light matches or overlaps with a wavelength or wavelength range of the second polarization of light.

The nanostructure elements of metastructure 110 may be formed from a relatively high dielectric index material, such as amorphous silicon (a-Si), crystalline silicon (c-Si), p-Si, silicon nitride (Si3N4), titanium dioxide (TiO2), gallium nitride (GaN), Zinc oxide (ZnO), hafnium silicate, zirconium silicate, hafnium dioxide and zirconium dioxide.

As shown, filter 115-a may be configured to allow a first wavelength (e.g., first wavelength range) and/or light in the first polarization state to pass to pixel 120-a (e.g., blocking other polarization states); allow a second wavelength (e.g., second wavelength range) and/or light in the second polarization state to pass to pixel 120-b (e.g., blocking other polarization states); and/or allow a third wavelength (e.g., third wavelength range) and/or light in the third polarization state to pass to pixel 120-c (e.g., blocking other polarization states).

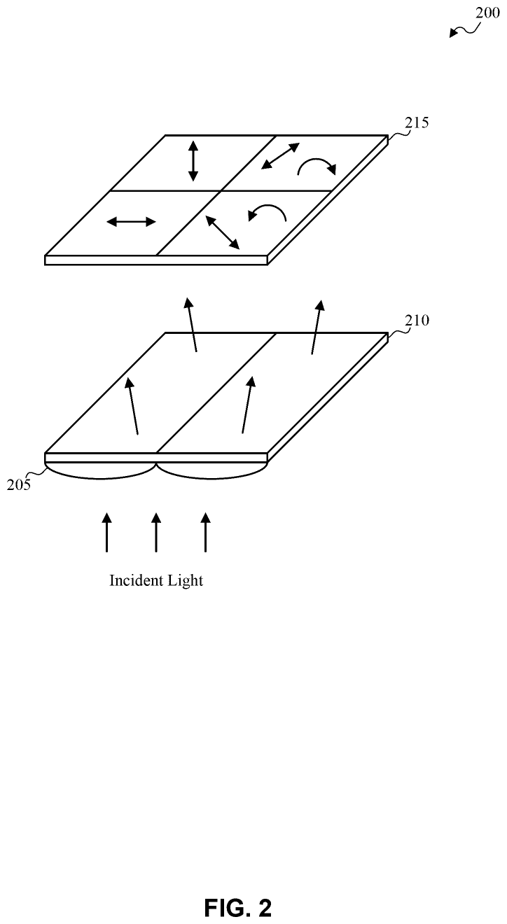

FIG. 2 illustrates an example system 200 in accordance with one or more implementations as described herein. In some configurations, one or more aspects of system 200 may be implemented by or in conjunction with a polarization sensor. In the illustrated example, system 200 may include microlens 205, filter 210, and sensor pixels 215. In some cases, filter 210 may be an example of metastructure 110 and/or filter 115 of FIG. 1. Sensor pixels 215 may be an example of sensor pixel array 120 of FIG. 1.

As shown, microlens 205 may include one or more elements (e.g., 1×2 microlens, bifurcated microlens). In the illustrated example, light may pass through microlens 205 to filter 210. In some examples, filter 210 may include a metastructure (e.g., nanostructure elements) configured to route the incident light based on properties of the light. In some cases, filter 210 may include one or more filters that filter the incident light based on the properties of the light. For example, filter 210 may route a first polarization state of the incident light (e.g., horizontal polarization) towards a first pixel of sensor pixels 215; route a second polarization state of the incident light (e.g., vertical polarization) towards a second pixel of sensor pixels 215; route a third polarization state of the incident light (e.g., diagonal polarization or right-handed circular polarization) towards a third pixel of sensor pixels 215; and/or route a fourth polarization state of the incident light (e.g., anti-diagonal polarization or left-handed circular polarization) towards a fourth pixel of sensor pixels 215.

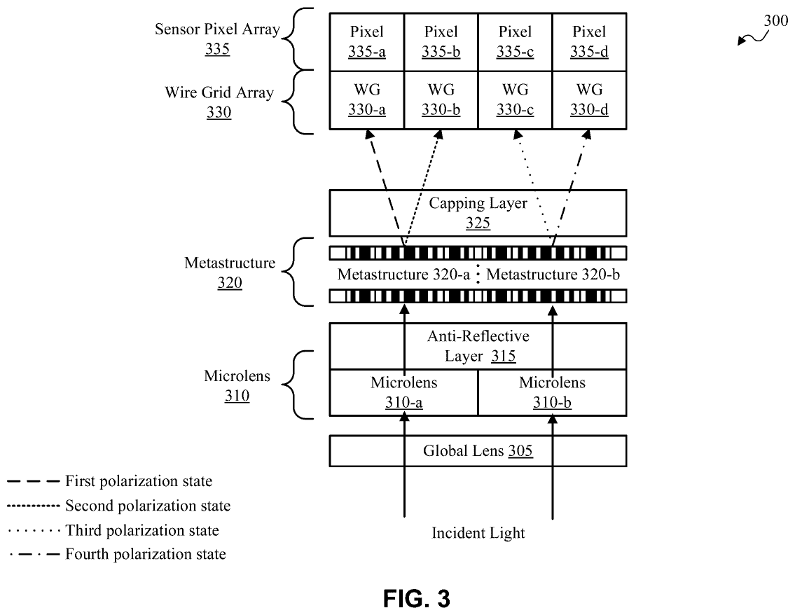

FIG. 3 illustrates an example system 300 in accordance with one or more implementations as described herein. In some configurations, one or more aspects of system 300 may be implemented by or in conjunction with a polarization sensor. In some configurations, one or more aspects of system 300 may be implemented by or in conjunction with one or more components of system 100 of FIG. 1, with one or more components of system 200 of FIG. 2, or any combination thereof. In the illustrated example, system 300 may include global lens 305, microlens 310, anti-reflective layer 315, metastructure 320, capping layer 325, wire grid array 330, and sensor pixel array 335.

As shown, light may pass through global lens 305 to microlens 310. Microlens 310 may include at least microlens 310-a and microlens 310-b. In some cases, microlens 310-a may pass a first portion of the incident light to anti-reflective layer 315, and microlens 310-b may pass a second portion of the incident light to anti-reflective layer 315. Anti-reflective layer 315 may include one or more anti-glare layers to reduce the amount of light that reflects back towards microlens 310, allowing more of the incident light to pass through to metastructure 320.

In some examples, metastructure 320 may include one or more layers (e.g., one or more layers of nanostructures). For example, metastructure 320 may include up to twelve metastructure layers. Metastructure 320 may route light through capping layer 325 towards wire grid array 330. In some cases, capping layer 325 may be configured to route light toward wire grid array 330 in conjunction with metastructure 320. Capping layer 325 may include a relatively low refractive index (e.g., less than 2). Capping layer 325 may include a dielectric or a polymer, such as aluminum oxide (Al2O3), silicon dioxide (SiO2), silicon nitride (Si3N4), silicon oxynitride (SixNyOz), silicon oxide (SiO), photoresists, epoxy resins and/or other materials. Capping layer 325 may be formed on a wire grid and/or surface of a detector substrate. Capping layer 325 may be substantially optically transparent, and may be formed by chemical vapor deposition (CVD), plasma enhanced CVD (PECVD), physical vapor deposition (PVD), atomic layer deposition (ALD), evaporation, spin-on coating, and/or other processes.

As shown, metastructure 320 may include at least metastructure 320-a and metastructure 320-b. Metastructure 320-a may be adjacent to metastructure 320-b, where microlens 310-a may align with metastructure 320-a and/or microlens 310-b may align with metastructure 320-b. In some cases, metastructure 320-a may include at least one metastructure layer and/or metastructure 320-b may include at least one metastructure layer. In some cases, metastructure 320-a and metastructure 320-b may route light based on one or more properties of the light (e.g., polarity of the light, wavelength of the light). For example, metastructure 320-a may be configured to route a first wavelength (e.g., first wavelength range) and/or a first polarization state of light (e.g., horizontal polarization) towards wire grid 330-a; and route a second wavelength (e.g., second wavelength range) and/or a second polarization state of the incident light (e.g., vertical polarization) towards wire grid 330-b. In some examples, metastructure 320-b may be configured to route a third wavelength (e.g., third wavelength range) and/or a third polarization state of the incident light (e.g., diagonal polarization or right-handed circular polarization) towards wire grid 330-c; and route a fourth wavelength (e.g., fourth wavelength range) and/or a fourth polarization state of the incident light (e.g., anti-diagonal polarization or left-handed circular polarization) towards wire grid 330-d.

As shown, wire grid array 330 may include at least one of wire grid 330-a, wire grid 330-b, wire grid 330-c, and/or wire grid 330-d. In some examples, wire grid array 330 may filter light based on one or more properties of the light. For example, wire grid 330-a may be configured to permit the first wavelength and/or first polarization state to pass through to pixel 335-a (e.g., while blocking other wavelengths and/or polarization states); wire grid 330-b may be configured to permit the second wavelength and/or second polarization state to pass through to pixel 335-b (e.g., while blocking other wavelengths and/or polarization states); wire grid 330-c may be configured to permit the third wavelength and/or third polarization state to pass through to pixel 335-c (e.g., while blocking other wavelengths and/or polarization states); and/or wire grid 330-d may be configured to permit the fourth wavelength and/or fourth polarization state to pass through to pixel 335-d (e.g., while blocking other wavelengths and/or polarization states).

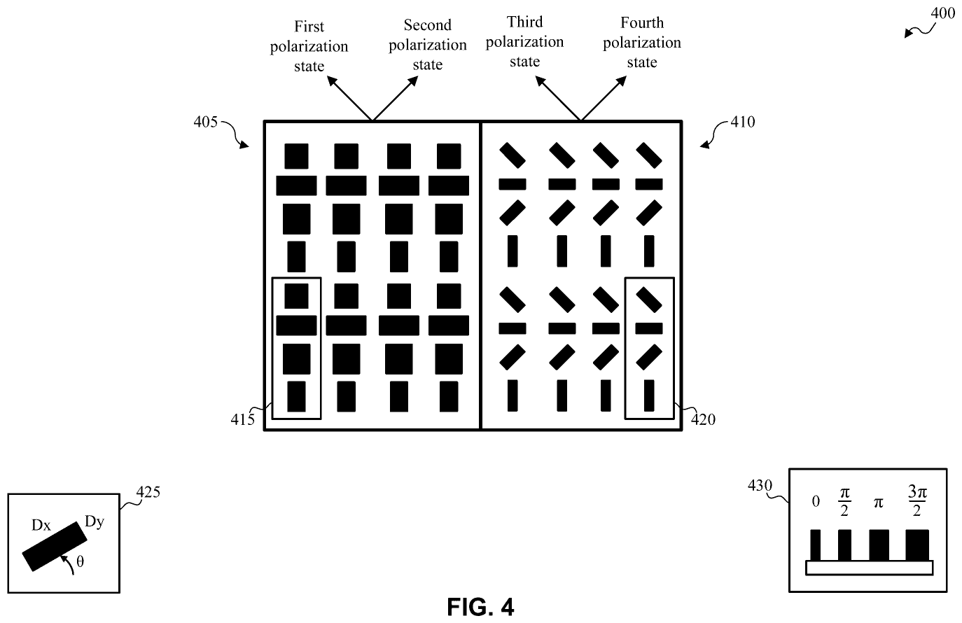

FIG. 4 illustrates an example metastructure 400 in accordance with one or more implementations as described herein. In some configurations, one or more aspects of metastructure 400 may be implemented by or in conjunction with a polarization sensor. In some configurations, one or more aspects of metastructure 400 may be implemented by or in conjunction with one or more components of system 100 of FIG. 1, with one or more components of system 200 of FIG. 2, or any combination thereof. In the illustrated example, metastructure 400 may include metastructure 405 and metastructure 410. In some cases, metastructure 405 may include one or more layers and/or metastructure 410 may include one or more layers. Although reference is made to routing polarization states of light throughput the provided description, the routing may include routing polarization states of light and/or wavelengths of light (e.g., wavelength ranges).

In the illustrated example, metastructure 405 and metastructure 410 may include, respectively, one or more nanostructure elements. In some cases, metastructure 405 and/or metastructure 410 may include a number of repeating nanostructure elements. For example, metastructure 405 may include period 415 with a number of nanostructure elements, where period 415 may repeat itself at least one time vertically and/or at least one time horizontally in the depicted example metastructure 405. As shown, metastructure 410 may include period 420 with a number of nanostructure elements, where period 420 may repeat itself at least one time vertically and/or at least one time horizontally in the depicted example metastructure 410. In some cases, period 415 and/or period 420 may include one or more nanostructure elements (e.g., up to 100 nanostructure elements). In the illustrated example, period 415 may include four nanostructure elements and period 420 may include four nanostructure elements.

As shown, metastructure 405 may be configured for routing at least one of a first polarization state and/or a second polarization state. In some examples, the first polarization state may include a horizontal polarization, and the second polarization state may include a vertical polarization. In some cases, the first polarization state and/or the second polarization state may include, respectively, other polarization states (e.g., diagonal polarization, anti-diagonal polarization, right-handed circular polarization, left-handed circular polarization). As shown, metastructure 405 may route and/or focus the first polarization state towards a first target location (e.g., towards a first wire gird and/or first sensor pixel of a photodetector). In some cases, metastructure 405 may route and/or focus the second polarization state towards a second target location (e.g., towards a second wire gird and/or second sensor pixel of the photodetector).

As shown, metastructure 410 may be configured for routing at least one of a third polarization state and/or a fourth polarization state. In some examples, the third polarization state may include a diagonal polarization, and the fourth polarization state may include an anti-diagonal polarization. In some cases, the third polarization state may include a right-handed circular polarization, and the fourth polarization state may include a left-handed circular polarization. In some cases, the third polarization state and/or the fourth polarization state may include, respectively, other polarization states (e.g., horizontal polarization, vertical polarization). As shown, metastructure 410 may route and/or focus the third polarization state towards a third target location (e.g., towards a third wire gird and/or third sensor pixel of the photodetector). In some cases, metastructure 410 may route and/or focus the fourth polarization state towards a fourth target location (e.g., towards a fourth wire gird and/or fourth sensor pixel of the photodetector).

In some examples, a given nanostructure element of metastructure 405 and/or metastructure 410 may include one or more dimensions 425. It is noted that a nanostructure element may have a width dimension (e.g., in the x axis), a length dimension (e.g., in the y axis), and a height (e.g., in the z axis). As shown, dimensions 425 of a given nanostructure element may include at least one of a width (e.g., Dx), a length (e.g., Dy), and/or an angle of rotation (e.g., 0). In some cases, a nanostructure element may be configured in a rectangular shape, a cylinder shape, a triangle shape, and/or some other shape. In some cases, metastructure 400 may depict a top-down view of nanostructure elements. In some cases, metastructure 400 may depict a side view of nanostructure elements.

In some examples, in a given period, a magnitude of Dx does not equal a magnitude of Dy for routing horizontal polarization, vertical polarization, diagonal polarization, anti-diagonal polarization, right-handed circular polarization, and/or left-handed circular polarization via metastructure 400. In a given period, the angle of rotation may equal zero for routing horizontal polarization and/or vertical polarization via metastructure 400. For routing horizontal polarization, vertical polarization, diagonal polarization and/or anti-diagonal polarization via metastructure 400, Dx of a first element of a given period may vary from Dx of a second element of the given period, and/or Dy of the first element of the given period may vary from Dy of the second element of the given period. In some cases, in a given period, the angle of rotation may be non-zero (e.g., avoid θ=0 degrees) for routing diagonal polarization, anti-diagonal polarization, right-handed circular polarization, and/or left-handed circular polarization via metastructure 400. In some cases, the angle of rotation may vary over a given period and/or remain constant over a given period for routing diagonal polarization, anti-diagonal polarization, right-handed circular polarization, and/or left-handed circular polarization via metastructure 400. For routing right-handed circular polarization and/or left-handed circular polarization via metastructure 400, Dx of a first element of a given period may match Dx of a second element of the given period, and/or Dy of the first element of the given period may match Dy of the second element of the given period.

In some examples, the nanostructure elements of metastructure 405 and/or metastructure 410 may provide up to a 2Pi radian phase shift to incident light based on the number of nanostructure elements in a given period (e.g., period 415, period 420). For example, neighboring nanostructures may include a 2Pi/n phase difference, where n represents the number of elements in a given period. For instance, as shown in 430, if there are 4 nanostructures in a given period, then a first nanostructure element may induce a 0 radians phase modulation to incident light; a second nanostructure element may induce a Pi/2 radians phase modulation to incident light; a third nanostructure element may induce a Pi radians phase modulation to incident light; and a fourth nanostructure element may induce a 3Pi/2 radians phase modulation to incident light.

Based on the systems and methods described herein, metastructure 400 may improve the light collection efficiency of a given system (e.g., of a polarization sensor). For example, based on metastructure 400, the systems and methods described avoid the efficiency limit of some systems (e.g., 25% limit for 2×2 polarization pixel systems), where metastructure 400 provide improved light collection efficiency for multiple polarization states (e.g., 44.89% light collection efficiency for horizontal polarization; 43.29% light collection efficiency for vertical polarization; 44.59% light collection efficiency for left-handed circular polarization; 44.61% light collection efficiency for right-handed circular polarization).

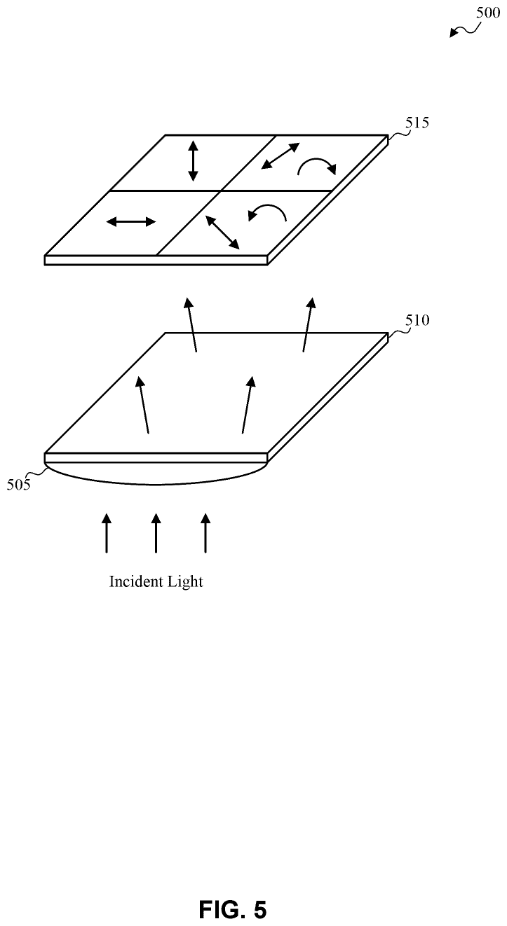

FIG. 5 illustrates an example system 500 in accordance with one or more implementations as described herein. In some configurations, one or more aspects of system 500 may be implemented by or in conjunction with a polarization sensor. In some configurations, one or more aspects of system 500 may be implemented by or in conjunction with one or more components of system 100 of FIG. 1, with one or more components of system 200 of FIG. 2, or any combination thereof. In the illustrated example, system 500 may include microlens 505, filter 510, and sensor pixels 515. In some cases, filter 510 may be an example of metastructure 110 and/or filter 115 of FIG. 1. Sensor pixels 515 may be an example of sensor pixel array 120 of FIG. 1.

As shown, microlens 505 may include one or more elements (e.g., 1×1 microlens, single microlens). In the illustrated example, light may pass through microlens 505 to filter 510. In some examples, filter 510 may include a metastructure (e.g., nanostructure elements) configured to route the incident light based on properties of the light. In some cases, filter 510 may include one or more filters that filter the incident light based on the properties of the light. For example, filter 510 may route a first polarization state of the incident light (e.g., horizontal polarization) towards a first pixel of sensor pixels 515; route a second polarization state of the incident light (e.g., vertical polarization) towards a second pixel of sensor pixels 515; route a third polarization state of the incident light (e.g., diagonal polarization or right-handed circular polarization) towards a third pixel of sensor pixels 515; and/or route a fourth polarization state of the incident light (e.g., anti-diagonal polarization or left-handed circular polarization) towards a fourth pixel of sensor pixels 515.

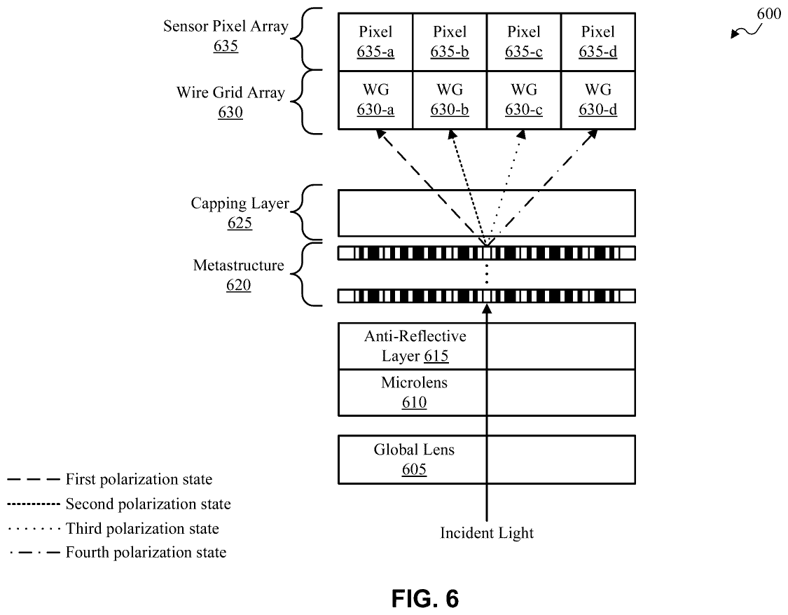

FIG. 6 illustrates an example system 600 in accordance with one or more implementations as described herein. In some configurations, one or more aspects of system 600 may be implemented by or in conjunction with a polarization sensor. In some configurations, one or more aspects of system 600 may be implemented by or in conjunction with one or more components of system 100 of FIG. 1, with one or more components of system 200 of FIG. 2, or any combination thereof. In the illustrated example, system 600 may include global lens 605, microlens 610, anti-reflective layer 615, metastructure 620, capping layer 625, wire grid array 630, and sensor pixel array 635.

As shown, light may pass through global lens 605 to microlens 610. Microlens 610 (e.g., a single microlens) may pass the incident light to anti-reflective layer 615. Anti-reflective layer 615 may include one or more anti-glare layers to reduce the amount of light that reflects back towards microlens 610, allowing more of the incident light to pass through to metastructure 620.

In some examples, metastructure 620 may include one or more layers (e.g., one or more layers of nanostructures). For example, metastructure 620 may include up to twelve metastructure layers. Metastructure 620 may route light through capping layer 625 towards wire grid array 630. In some cases, capping layer 625 may be configured to route light toward wire grid array 630 in conjunction with metastructure 620. Capping layer 625 may include a relatively low refractive index (e.g., less than 2). In some cases, capping layer 625 may improve the luminance and/or power efficiency in routing light towards wire grid array 630. As shown, wire grid array 630 may include at least one of wire grid 630-a, wire grid 630-b, wire grid 630-c, and/or wire grid 630-d.

In some cases, metastructure 620 may route light based on one or more properties of the light (e.g., polarization of light, wavelength of light, etc.). For example, metastructure 620 may route a first wavelength (e.g., first wavelength range) and/or a first polarization state of light (e.g., horizontal polarization) towards wire grid 630-a; route a second wavelength (e.g., second wavelength range) and/or a second polarization state of the incident light (e.g., vertical polarization) towards wire grid 630-b; route a third wavelength (e.g., third wavelength range) and/or a third polarization state of the incident light (e.g., diagonal polarization or right-handed circular polarization) towards wire grid 630-c; and/or route a fourth wavelength (e.g., fourth wavelength range) and/or a fourth polarization state of the incident light (e.g., anti-diagonal polarization or left-handed circular polarization) towards wire grid 630-d. Accordingly, metastructure 620 may receive light that includes up to four polarization states and/or wavelengths and may be configured to route these four polarization states and/or wavelengths to different target locations. Based on the systems and methods described herein, metastructure 620 may improve the light collection efficiency of a given system (e.g., up to or relatively near 100% light collection efficiency).

In some examples, wire grid array 630 may filter light based on one or more properties of the light. For example, wire grid 630-a may be configured to permit the first wavelength and/or the first polarization state to pass through to pixel 635-a (e.g., while blocking other wavelengths and/or polarization states); wire grid 630-b may be configured to permit the second wavelength and/or the second polarization state to pass through to pixel 635-b (e.g., while blocking other wavelengths and/or polarization states); wire grid 630-c may be configured to permit the third wavelength and/or the third polarization state to pass through to pixel 635-c (e.g., while blocking other wavelengths and/or polarization states); and/or wire grid 630-d may be configured to permit the fourth wavelength and/or the fourth polarization state to pass through to pixel 635-d (e.g., while blocking other wavelengths and/or polarization states).

Accordingly, the systems and methods described herein provide polarization sensors with on-chip polarization routing. A given system may include a lens, at least one microlens, at least one metastructure, a wire grid array, and/or at least one photodetector. The metastructure may include anisotropic nanostructures (e.g., nanostructure elements of varying widths, lengths, and/or rotational orientations).

In some examples, the metastructure may filter and route by polarization state or by polarization state and wavelength range to a given wire grid module in the wire grid array. The metastructure may filter and route a number of polarization states (e.g., four, two, or all polarization states) to at least one wire grid.

In some examples, the metastructure may include a phase modulating nanostructure. In some cases, a given set of nanostructure elements of a metastructure may include N nanostructures, where N is a positive integer (e.g., from 2 to 100). In some cases, the given set of nanostructure elements may repeat one or more times in the metastructure (e.g., a set of nanostructure elements that repeat periodically). A first nanostructure element in the set may have a phase difference of 2pi/N relative to a second nanostructure element in the set. In some cases, the first nanostructure element may be adjacent to the second nanostructure element, where the shape of each respective element creates the phase difference.

A pattern of a given set of nanostructure elements (e.g., periodicity, pixel size/N) may allow for wavelength range and polarization states to be filtered to a target location. The metastructure may include one or more patterns that may vary throughout the metastructure. In some examples, the variations in patterns may vary based on changes in nanostructure shape (e.g., length, width, length-to-width ratio changes) and/or changes in rotational orientation (e.g., varying rotations to change the angle of light polarization) throughout the metasurface).

In some examples, the wire grid array may include at least one wire grid module, where a given wire grid module may filter at least one polarization state. The metastructure may guide light and filter by polarization state. The metastructure may filter and route light by wavelength range to a given wire grid. In some cases, the microlens may include an anti-reflective layer. In some cases, the microlens may be embedded on top of a given sensor pixel. In some implementations, the metastructure may include a capping layer with a relatively low refractive index to allow for light routing. The wire grid may include a combination of metals and/or metal/semiconductor dielectrics (e.g., metal oxides, nitrides, silicon dioxide, etc.).

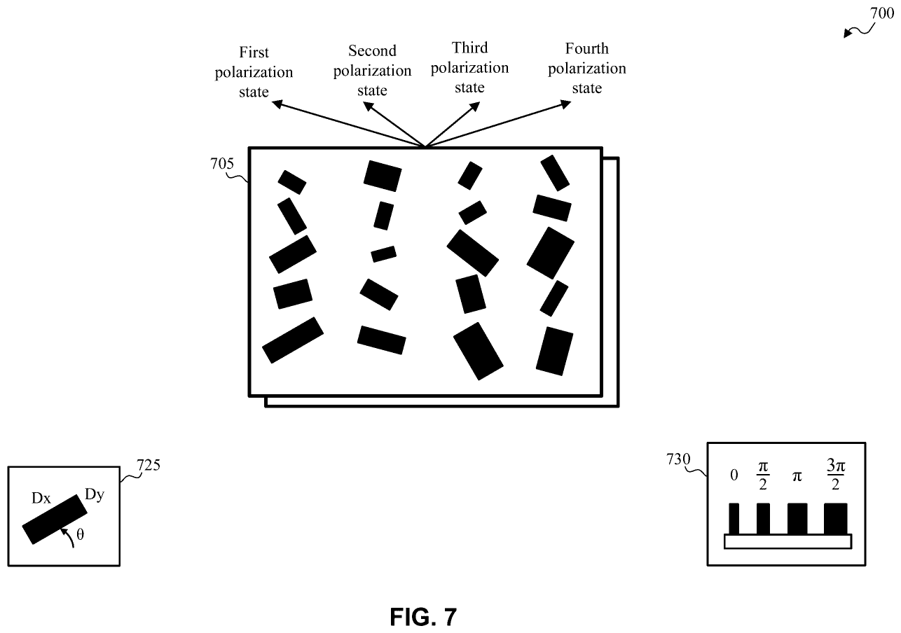

FIG. 7 illustrates an example metastructure 700 in accordance with one or more implementations as described herein. In some configurations, one or more aspects of metastructure 700 may be implemented by or in conjunction with a polarization sensor. In some configurations, one or more aspects of metastructure 700 may be implemented by or in conjunction with one or more components of system 100 of FIG. 1, with one or more components of system 200 of FIG. 2, or any combination thereof. In the illustrated example, metastructure 700 may include metastructure 705. As shown, metastructure 705 may include one or more layers. Although reference is made to routing polarization states of light throughput the provided description, the routing may include routing polarization states of light and/or wavelengths of light (e.g., wavelength ranges).

In the illustrated example, metastructure 705 may include one or more nanostructure elements. In some cases, metastructure 705 may include a number of repeating nanostructure elements. For example, metastructure 705 may include a number of nanostructure elements that periodically repeat (e.g., repeat at least one time vertically and/or repeat at least one time horizontally in the depicted example metastructure 705).

As shown, metastructure 705 may be configured for routing at least one of a first polarization state, a second polarization state, a third polarization state, and/or a fourth polarization state. In some examples, the first polarization state may include a horizontal polarization, the second polarization state may include a vertical polarization, the third polarization state may include a diagonal polarization, and the fourth polarization state may include an anti-diagonal polarization. In some cases, the third polarization state may include a right-handed circular polarization, and the fourth polarization state may include a left-handed circular polarization. As shown, metastructure 705 may route and/or focus the first polarization state towards a first target location (e.g., towards a first wire gird and/or first sensor pixel of a photodetector); route and/or focus the second polarization state towards a second target location (e.g., towards a second wire gird and/or second sensor pixel of the photodetector); route and/or focus the third polarization state towards a third target location (e.g., towards a third wire gird and/or third sensor pixel of the photodetector); and/or route and/or focus the fourth polarization state towards a fourth target location (e.g., towards a fourth wire gird and/or fourth sensor pixel of the photodetector).

In some examples, a given nanostructure element of metastructure 705 may include one or more dimensions 725. As shown, dimensions 725 of a given nanostructure element may include at least one of a width (e.g., Dx), a length (e.g., Dy), and/or an angle of rotation (e.g., θ). In some cases, a nanostructure element of metastructure 705 may be configured in a rectangular shape, a cylinder shape, a triangle shape, and/or some other shape. In some cases, metastructure 705 may depict a top-down view of nanostructure elements. In some cases, metastructure 705 may depict a side view of nanostructure elements.

In some examples, in a given period, a magnitude of Dx does not equal a magnitude of Dy for routing horizontal polarization, vertical polarization, diagonal polarization, anti-diagonal polarization, right-handed circular polarization, and/or left-handed circular polarization via metastructure 700. In some cases, in a given period, the angle of rotation may be non-zero (e.g., avoid θ=0 degrees) for routing horizontal polarization, vertical polarization, diagonal polarization, anti-diagonal polarization, right-handed circular polarization, and/or left-handed circular polarization via metastructure 700. In some cases, the angle of rotation may vary over a given period for routing horizontal polarization, vertical polarization, diagonal polarization, anti-diagonal polarization, right-handed circular polarization, and/or left-handed circular polarization via metastructure 700. For routing horizontal polarization, vertical polarization, diagonal polarization anti-diagonal polarization, right-handed circular polarization, and/or left-handed circular polarization via metastructure 700, Dx of a first element of a given period may vary from Dx of a second element of the given period, and/or Dy of the first element of the given period may vary from Dy of the second element of the given period.

In some examples, the nanostructure elements of metastructure 705 may provide up to a 2Pi radian phase shift to incident light based on the number of nanostructure elements in a given period (e.g., period 715, period 720). For example, neighboring nanostructures may include a 2Pi/n phase difference, where n represents the number of elements in a given period. Thus, as shown in 730, if there are 4 nanostructures in a given period, then a first nanostructure element may induce a 0 radians phase modulation to incident light; a second nanostructure element may induce a Pi/2 radians phase modulation to incident light; a third nanostructure element may induce a Pi radians phase modulation to incident light; and a fourth nanostructure element may induce a 3Pi/2 radians phase modulation to incident light.

Based on the systems and methods described herein, metastructure 705 may improve the light collection efficiency of a given system (e.g., of a polarization sensor). For example, based on metastructure 705, the systems and methods described avoid the efficiency limit of some systems (e.g., 25% limit for 2×2 polarization pixel systems), where metastructure 705 provides improved light collection efficiency for multiple polarization states (e.g., up to or relatively near 100% light collection efficiency for routing horizontal polarization, vertical polarization, diagonal polarization, anti-diagonal polarization, right-handed circular polarization, and/or left-handed circular polarization).

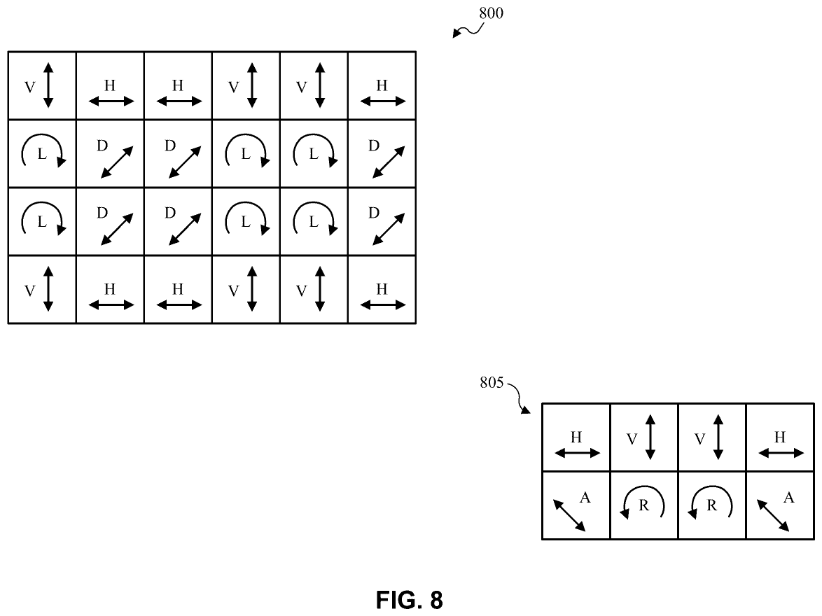

FIG. 8 illustrates an example pattern 800 in accordance with one or more implementations as described herein. In some configurations, one or more aspects of pattern 800 may be implemented by or in conjunction with a polarization sensor. In some configurations, one or more aspects of pattern 800 may be implemented by or in conjunction with one or more components of system 100 of FIG. 1, with one or more components of system 200 of FIG. 2, or any combination thereof.

In the illustrated example, pattern 800 may depict a polarization sensing pattern of a sensor pixel array (e.g., sensor pixel array 120, sensor pixel array 335, sensor pixel array 635). For example, pattern 800 may depict a polarization sensing pattern for sensing vertical polarization (e.g., V sensor pixels), horizontal polarization (e.g., H sensor pixels), diagonal polarization (e.g., D sensor pixels), and left-handed circular polarization (e.g., L sensor pixels). For instance, a metastructure (e.g., metastructure 320, metastructure 620) may route vertical polarization to V sensor pixels of pattern 800; route horizontal polarization to H sensor pixels of pattern 800; route diagonal polarization to D sensor pixels of pattern 800; and/or route left-handled circular polarization to L sensor pixels of pattern 800.

As shown, pattern 800 may include a repeating pattern. For example, pattern 800 may include a repeating VHDL, HVLD polarization sensing pattern. In some cases, the repeating VHDL, HVLD polarization sensing pattern of pattern 800 may enable a given system to determine the intensity of anti-diagonal polarization and/or right-handed circular polarization based on measuring the vertical polarization, horizontal polarization, diagonal polarization, and left-handed circular polarization according to pattern 800 (e.g., detect six polarization states based on measuring four polarization states). For example, pattern 800 may provide Full Stokes Polarization, or a complete characterization of the polarization state of light based on measuring the vertical polarization, horizontal polarization, diagonal polarization, and left-handed circular polarization. In some examples, four polarization sensor pixels may be used to detect six polarization states based on the following equations:

$${I}_{H} = {I}_{H}$$

$${I}_{V} = {I}_{V}$$

$${I}_{D} = {I}_{D}$$

$${I}_{L} = {I}_{L}$$

$${I}_{A} = {I}_{H} + {I}_{V} - {I}_{D}$$

$${I}_{R} = {I}_{H} + {I}_{V} - {I}_{L}$$

As shown, the intensity of horizontal polarization light may be measured by one or more H sensor pixels, the intensity of vertical polarization light may be measured by one or more V sensor pixels, the intensity of diagonal polarization light may be measured by one or more D sensor pixels, and the intensity of left-handed circular polarization light may be measured by a one or more L sensor pixels. Also, the intensity of anti-diagonal polarization may be determined based on the measurements of intensity for horizontal, vertical, and diagonal polarization. And the intensity of right-handed circular polarization may be determined based on the measurements of intensity for horizontal, vertical, and left-handed circular polarization.

In some examples, based on the polarization states measured according to pattern 800, the following Stokes parameters may be determined:

$${S}_{0} = {I}_{H} + {I}_{V}$$

$${S}_{1} = {I}_{H} - {I}_{V}$$

$${S}_{2} = 2 * {I}_{D} - {S}_{0}$$

$${S}_{3} = 2 * {I}_{L} - {S}_{0}$$

$$DoLP = \frac{\sqrt{{s}_{1}^{2} + {s}_{2}^{2}}}{{s}_{0}}$$

$$AoLP = \frac{1}{2} {tan}^{- 1} \frac{S 2}{S 1}$$

As shown, S₀ may be based on the intensity of horizontal polarization and vertical polarization; S₁ may be based on the intensity of horizontal polarization and vertical polarization; S₂ may be based on the intensity of diagonal polarization and S₀; and S₃ may be based on the intensity of left-handed circular polarization and S₀. In some cases, S₁, S₂, and S₃ may represent a three-dimensional vector of Cartesian coordinates (S₁, S₂, S₃), where S₀ may represent the total intensity of a given beam. As shown, the Stokes parameter calculations may provide the degree of linear polarization (DoLP) and/or angle of linear polarization (AoLP) as indicated.

In some examples, the six polarization states may be determined based on a variation of pattern 800. As shown, pattern 805 may provide polarization sensing for horizontal polarization (H), vertical polarization (V), anti-diagonal polarization (A), and right-handed circular polarization (R). For example, pattern 805 may depict a polarization sensing pattern for sensing horizontal polarization (e.g., H sensor pixels), vertical polarization (e.g., V sensor pixels), anti-diagonal polarization (e.g., A sensor pixels), and right-handed circular polarization (e.g., R sensor pixels). For instance, a metastructure (e.g., metastructure 320, metastructure 620) may route vertical polarization to V sensor pixels of pattern 805; route horizontal polarization to H sensor pixels of pattern 805; route anti-diagonal polarization to A sensor pixels of pattern 805; and/or route right-handled circular polarization to R sensor pixels of pattern 805.

As shown, pattern 805 may include a repeating pattern. For example, pattern 805 may include a repeating HVRA, VHAR polarization sensing pattern. In some cases, the repeating HVRA, VHAR polarization sensing pattern of pattern 805 may enable a given system to determine the intensity of diagonal polarization and/or left-handed circular polarization based on measuring the horizontal polarization, vertical polarization, anti-diagonal polarization, and right-handed circular polarization according to pattern 805 (e.g., detect six polarization states based on measuring four polarization states). For example, pattern 805 may provide Full Stokes Polarization, or a complete characterization of the polarization state of light based on measuring the horizontal polarization, vertical polarization, anti-diagonal polarization, and right-handed circular polarization. In some examples, four polarization sensor pixels may be used to detect six polarization states based on the equations provided above.

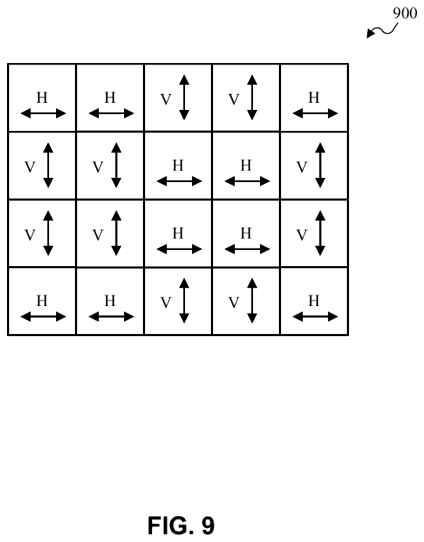

FIG. 9 illustrates an example pattern 900 in accordance with one or more implementations as described herein. In some configurations, one or more aspects of pattern 900 may be implemented by or in conjunction with a polarization sensor. In some configurations, one or more aspects of pattern 900 may be implemented by or in conjunction with one or more components of system 100 of FIG. 1, with one or more components of system 200 of FIG. 2, or any combination thereof.

When full-Stokes detection is not needed, other configurations may be used that not only simplify the sensor pixel configuration, but increase the efficiency rating of the given photodetector. To improve signal collection and binning, similar pixels together may be arranged together. Depending on the constraints of a given application, a sensor pixel configuration or a configuration of at least a subsection of a photodetector may be linear-based or circular-based (e.g., only linear-based polarization sensor pixels; only circular-based polarization sensor pixels). For example, for applications that do not rely on circular polarization, the sensor pixels may be configured for linear polarization. Similarly, for applications that do not rely on linear polarization, the sensor pixels may be configured for circular polarization. Designing the configuration in line with the constraints of the application improves the efficiency rating of a given photodetector.

In the illustrated example, pattern 900 may depict a polarization sensing pattern of a sensor pixel array (e.g., sensor pixel array 120, sensor pixel array 335, sensor pixel array 635). For example, pattern 900 may depict a polarization sensing pattern for sensing vertical polarization (e.g., V sensor pixels) and horizontal polarization (e.g., H sensor pixels). In some cases, the systems and methods described may include arranging similar pixels together (e.g., VV, HH, VV, etc.) to improve signal collection and/or binning detection.

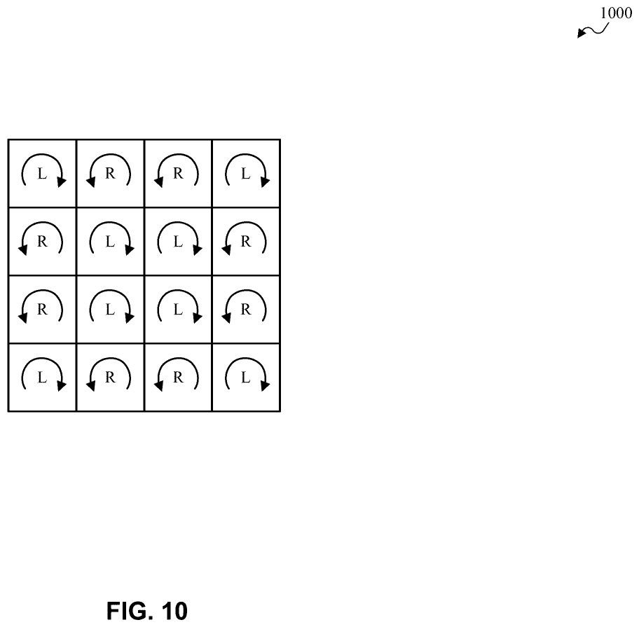

FIG. 10 illustrates an example pattern 1000 in accordance with one or more implementations as described herein. In some configurations, one or more aspects of pattern 1000 may be implemented by or in conjunction with a polarization sensor. In some configurations, one or more aspects of pattern 1000 may be implemented by or in conjunction with one or more components of system 100 of FIG. 1, with one or more components of system 200 of FIG. 2, or any combination thereof.

In the illustrated example, pattern 1000 may depict a polarization sensing pattern of a sensor pixel array (e.g., sensor pixel array 120, sensor pixel array 335, sensor pixel array 635). Pattern 1000 may be configured for detecting circular polarization states. For example, pattern 1000 may depict a polarization sensing pattern for sensing right-handed circular polarization (e.g., R sensor pixels) and left-handed circular polarization (e.g., L sensor pixels). In some cases, the systems and methods described may include arranging similar pixels together (e.g., RR, LL, RR, etc.) to improve signal collection and/or binning detection.

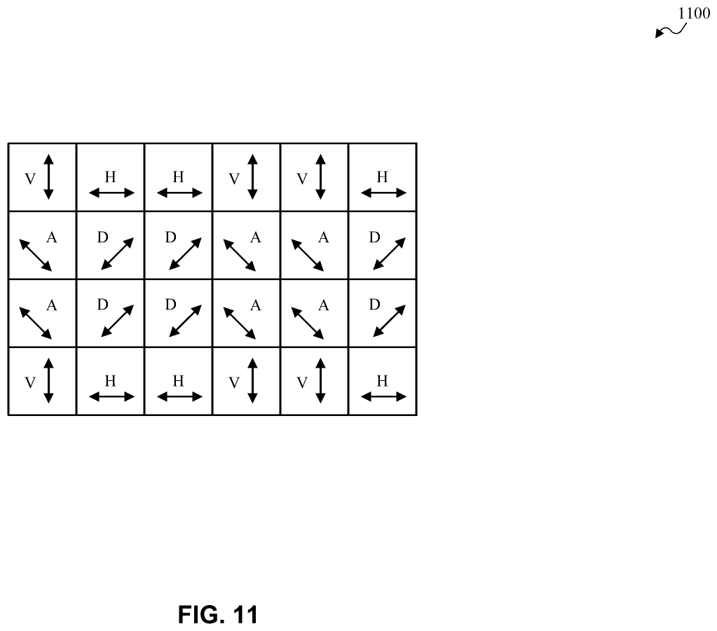

FIG. 11 illustrates an example pattern 1100 in accordance with one or more implementations as described herein. In some configurations, one or more aspects of pattern 1100 may be implemented by or in conjunction with a polarization sensor. In some configurations, one or more aspects of pattern 1100 may be implemented by or in conjunction with one or more components of system 100 of FIG. 1, with one or more components of system 200 of FIG. 2, or any combination thereof.

In the illustrated example, pattern 1100 may depict a polarization sensing pattern of a sensor pixel array (e.g., sensor pixel array 120, sensor pixel array 335, sensor pixel array 635). Pattern 1100 may be configured for detecting complete linear polarization states. For example, pattern 1100 may depict a polarization sensing pattern for sensing vertical polarization (e.g., V sensor pixels), horizontal polarization (e.g., H sensor pixels), anti-diagonal polarization (e.g., A sensor pixels), and diagonal polarization (e.g., D sensor pixels). In some cases, the systems and methods described may include arranging similar pixels together (e.g., VV, HH, DD, AA, etc.) to improve signal collection and/or binning detection.

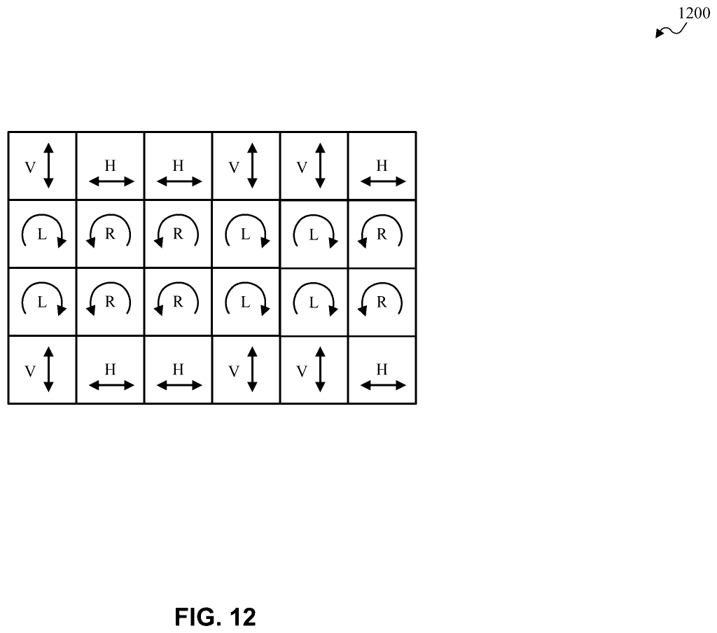

FIG. 12 illustrates an example pattern 1200 in accordance with one or more implementations as described herein. In some configurations, one or more aspects of pattern 1200 may be implemented by or in conjunction with a polarization sensor. In some configurations, one or more aspects of pattern 1200 may be implemented by or in conjunction with one or more components of system 100 of FIG. 1, with one or more components of system 200 of FIG. 2, or any combination thereof.

In the illustrated example, pattern 1200 may depict a polarization sensing pattern of a sensor pixel array (e.g., sensor pixel array 120, sensor pixel array 335, sensor pixel array 635). Pattern 1200 may be configured for detecting a combination of linear and circular polarization states. For example, pattern 1200 may depict a polarization sensing pattern for sensing vertical polarization (e.g., V sensor pixels), horizontal polarization (e.g., H sensor pixels), right-handed circular polarization (e.g., R sensor pixels), and left-handed circular polarization (e.g., L sensor pixels). In some cases, the systems and methods described may include arranging similar pixels together (e.g., VV, HH, LL, RR, etc.) to improve signal collection and/or binning detection.

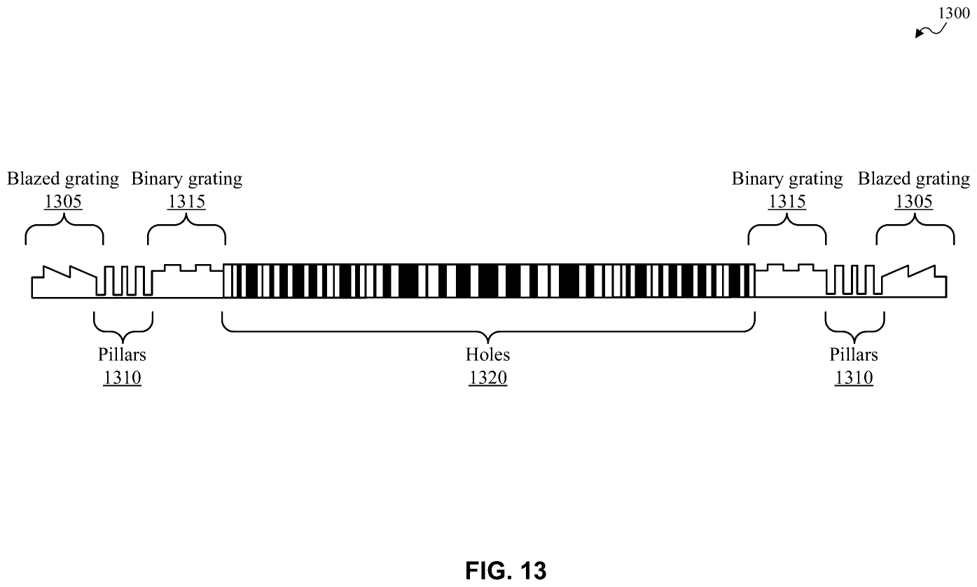

FIG. 13 illustrates an example metastructure 1300 in accordance with one or more implementations as described herein. In some examples, metastructure 1300 depicts a side view of a metalens that may be part of a thermal imaging system, such as thermal imaging system 100 of FIG. 1 and/or thermal imaging system 200 of FIG. 2. Metastructure 1300 may be an example of metastructure 320 of FIG. 3 and/or metastructure 620 of FIG. 6.

Metastructure 1300 may include at least one nanostructure element. In some cases, a top surface of metastructure 1300 may include one or more nanostructure elements. Additionally, or alternatively, a bottom surface of metastructure 1300 may include one or more nanostructure elements. In some examples, at least one nanostructure element of metastructure 1300 may be formed based on dry etching and/or wet etching.

In the illustrated example, metastructure 1300 may include nanostructure elements such as blazed gratings 1305, pillars 1310, binary gratings 1315, and holes 1320. In some examples, metastructure 1300 may include one or more patterns of diffraction grating (e.g., a pattern of blazed grating 1305 and/or binary grating 1315). In some cases, pillars 1310 may include one or more patterns of pillars. In some implementations, holes 1320 may include one or more patterns of holes (e.g., of a silicon hole-based metalens).

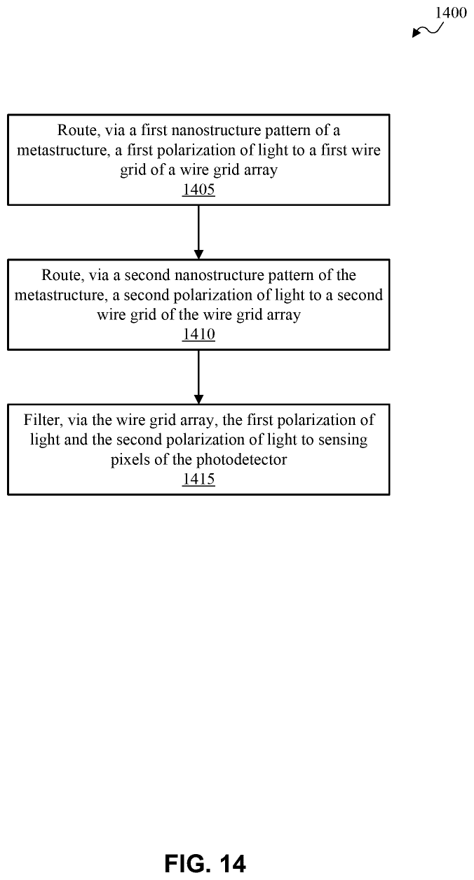

FIG. 14 depicts a flow diagram illustrating an example method 1400 associated with the disclosed systems, in accordance with example implementations described herein. In some configurations, one or more aspects of method 1400 may be implemented by or in conjunction with a polarization sensor. The depicted method 1400 is just one implementation and one or more operations of method 1400 may be rearranged, reordered, omitted, and/or otherwise modified such that other implementations are possible and contemplated.

At 1405, method 1400 may include routing, via a first nanostructure pattern of a metastructure, a first polarization of light to a first wire grid of a wire grid array. For example, a first nanostructure pattern of a metastructure may be configured to route a first polarization of light to a first wire grid of the wire grid array.

At 1410, method 1400 may include routing, via a second nanostructure pattern of the metastructure, a second polarization of light to a second wire grid of the wire grid array. For example, a second nanostructure pattern of the metastructure may route a second polarization of light different from the first polarization of light to a second wire grid of the wire grid array.

At 1415, method 1400 may include filtering, via the wire grid array, the first polarization of light and the second polarization of light to sensor pixels of the photodetector. For example, the wire grid array may filter the first polarization of light and filter the second polarization of light in relation to one or more sensor pixels of the photodetector.

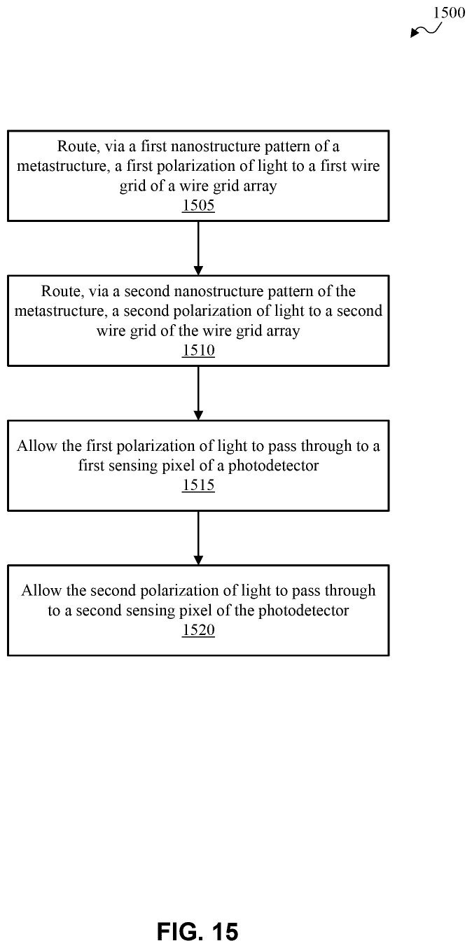

FIG. 15 depicts a flow diagram illustrating an example method 1500 associated with the disclosed systems, in accordance with example implementations described herein. In some configurations, one or more aspects of method 1500 may be implemented by or in conjunction with a polarization sensor. The depicted method 1500 is just one implementation and one or more operations of method 1500 may be rearranged, reordered, omitted, and/or otherwise modified such that other implementations are possible and contemplated.

At 1505, method 1500 may include routing, via a first nanostructure pattern of a metastructure, a first polarization of light to a first wire grid of a wire grid array. For example, a first nanostructure pattern of a metastructure may be configured to route a first polarization of light to a first wire grid of the wire grid array.

At 1510, method 1500 may include routing, via a second nanostructure pattern of the metastructure, a second polarization of light to a second wire grid of the wire grid array. For example, a second nanostructure pattern of the metastructure may route a second polarization of light different from the first polarization of light to a second wire grid of the wire grid array.

At 1515, method 1500 may include allowing the first polarization of light to pass through to a first sensor pixels of a photodetector. For example, the first wire grid of the wire grid array may be configured to allow the first polarization of light to pass through to a first sensor pixels of the photodetector and reflect the second polarization of light away from the first sensor pixels.

At 1520, method 1500 may include allowing the second polarization of light to pass through to a second sensor pixels of the photodetector. For example, the second wire grid of the wire grid array may be configured to allow the second polarization of light to pass through to a second sensor pixels of the photodetector and reflect the first polarization of light away from the second sensor pixels of the photodetector.

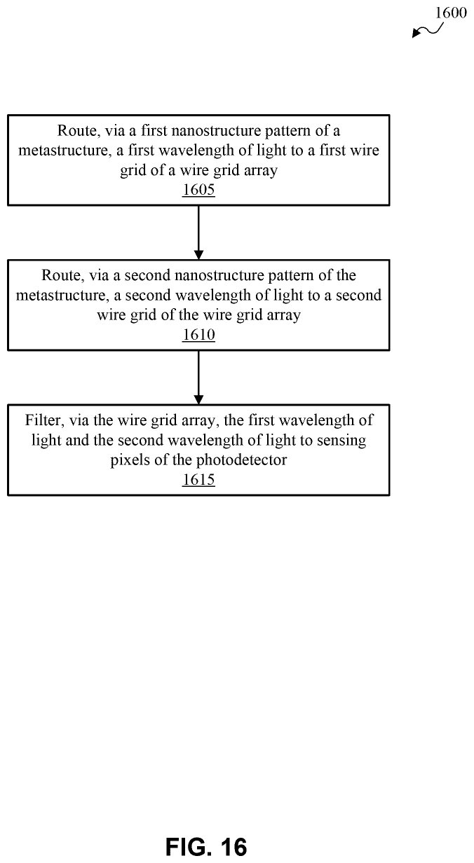

FIG. 16 depicts a flow diagram illustrating an example method 1600 associated with the disclosed systems, in accordance with example implementations described herein. In some configurations, one or more aspects of method 1600 may be implemented by or in conjunction with a polarization sensor. The depicted method 1600 is just one implementation and one or more operations of method 1600 may be rearranged, reordered, omitted, and/or otherwise modified such that other implementations are possible and contemplated.

At 1605, method 1600 may include routing, via a first nanostructure pattern of a metastructure, a first wavelength of light (e.g., first wavelength range) to a first wire grid of a wire grid array. For example, a first nanostructure pattern of a metastructure may be configured to route a first wavelength of light to a first wire grid of the wire grid array.

At 1610, method 1600 may include routing, via a second nanostructure pattern of the metastructure, a second wavelength of light (e.g., second wavelength range) to a second wire grid of the wire grid array. For example, a second nanostructure pattern of the metastructure may route a second wavelength of light different from the first wavelength of light to a second wire grid of the wire grid array.

At 1615, method 1600 may include filtering, via the wire grid array, the first wavelength of light and the second wavelength of light to sensor pixels of the photodetector. For example, the wire grid array may filter the first wavelength of light and filter the second wavelength of light in relation to one or more sensor pixels of the photodetector.

Embodiments of the subject matter and the operations described in this specification may be implemented in digital electronic circuitry, or in computer software, firmware, or hardware, including the structures disclosed in this specification and their structural equivalents, or in combinations of one or more of them. Embodiments of the subject matter described in this specification may be implemented as one or more computer programs, i.e., one or more modules of computer-program instructions, encoded on computer-storage medium for execution by, or to control the operation of data-processing apparatus. Alternatively or additionally, the program instructions can be encoded on an artificially-generated propagated signal, e.g., a machine-generated electrical, optical, or electromagnetic signal, which is generated to encode information for transmission to suitable receiver apparatus for execution by a data processing apparatus. A computer-storage medium can be, or be included in, a computer-readable storage device, a computer-readable storage substrate, a random or serial-access memory array or device, or a combination thereof. Moreover, while a computer-storage medium is not a propagated signal, a computer-storage medium may be a source or destination of computer-program instructions encoded in an artificially-generated propagated signal. The computer-storage medium can also be, or be included in, one or more separate physical components or media (e.g., multiple CDs, disks, or other storage devices). Additionally, the operations described in this specification may be implemented as operations performed by a data-processing apparatus on data stored on one or more computer-readable storage devices or received from other sources.

While this specification may contain many specific implementation details, the implementation details should not be construed as limitations on the scope of any claimed subject matter, but rather be construed as descriptions of features specific to particular embodiments. Certain features that are described in this specification in the context of separate embodiments may also be implemented in combination in a single embodiment. Conversely, various features that are described in the context of a single embodiment may also be implemented in multiple embodiments separately or in any suitable sub-combination. Moreover, although features may be described above as acting in certain combinations and even initially claimed as such, one or more features from a claimed combination may in some cases be excised from the combination, and the claimed combination may be directed to a sub-combination or variation of a sub-combination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the embodiments described above should not be understood as requiring such separation in all embodiments, and it should be understood that the described program components and systems can generally be integrated together in a single software product or packaged into multiple software products.

Thus, particular embodiments of the subject matter have been described herein. Other embodiments are within the scope of the following claims. In some cases, the actions set forth in the claims may be performed in a different order and still achieve desirable results. Additionally, the processes depicted in the accompanying figures do not necessarily require the particular order shown, or sequential order, to achieve desirable results. In certain implementations, multitasking and parallel processing may be advantageous.

As will be recognized by those skilled in the art, the innovative concepts described herein may be modified and varied over a wide range of applications. Accordingly, the scope of claimed subject matter should not be limited to any of the specific exemplary teachings discussed above, but is instead defined by the following claims.

What is claimed is:

1. A polarization sensor comprising:
a metastructure comprising two or more nanostructure patterns that are configured to route polarization states of light towards a photodetector of the polarization sensor, the two or more nanostructure patterns comprising:
a first nanostructure pattern configured to route a first polarization of light to a first wire grid of a wire grid array, and
a second nanostructure pattern configured to route a second polarization of light different from the first polarization of light to a second wire grid of the wire grid array; and
the wire grid array configured to filter the first polarization of light and the second polarization of light to sensor pixels of the photodetector.

2. The polarization sensor of claim 1, wherein:
the first wire grid of the wire grid array is configured to allow the first polarization of light of a first wavelength to pass through to a first sensor pixels of the photodetector and reflect or absorb the second polarization of light away from the first sensor pixels, and
the second wire grid of the wire grid array is configured to allow the second polarization of light of the first wavelength to pass through to a second sensor pixels of the photodetector and reflect or absorb the first polarization of light away from the second sensor pixels of the photodetector.

3. The polarization sensor of claim 1, wherein:
the first nanostructure pattern is configured to route a first wavelength of light to the first wire grid of the wire grid array, and
the second nanostructure pattern is configured to route a second wavelength of light different from the first wavelength of light to the second wire grid of the wire grid array.

4. The polarization sensor of claim 1, further comprising:
a third nanostructure pattern of the metastructure configured to route a third polarization of light to a third wire grid of the wire grid array; and
a fourth nanostructure pattern of the metastructure configured to route a fourth polarization of light different from the third polarization of light to a fourth wire grid of the wire grid array.

5. The polarization sensor of claim 4, wherein:
the third wire grid of the wire grid array is configured to allow the third polarization of light to pass through to a third sensor pixels of the photodetector and reflect or absorb the fourth polarization of light away from the third sensor pixels, and
the fourth wire grid of the wire grid array is configured to allow the fourth polarization of light to pass through to a fourth sensor pixels of the photodetector and reflect or absorb the third polarization of light away from the fourth sensor pixels of the photodetector.

6. The polarization sensor of claim 1, wherein:
the first nanostructure pattern comprises N nanostructure elements that repeat at least one time in the metastructure, and
the second nanostructure pattern comprises M nanostructure elements that repeat at least one time in the metastructure, the M nanostructure elements being less, more, or same in number as the N nanostructure elements.

7. The polarization sensor of claim 6, wherein:
a first nanostructure element of the N nanostructure elements varies in phase from a second nanostructure element of the N nanostructure elements, and
the variation in phase is based on a quotient of Pi and N.

8. The polarization sensor of claim 1, wherein:
a width of a first nanostructure element of a repeating set of nanostructure elements of the metastructure does not match a length of the first nanostructure element,
a rotational orientation of the first nanostructure element matches a rotational orientation of a second nanostructure element of the repeating set of nanostructure elements, or
a rotational orientation of a third nanostructure element of the repeating set of nanostructure elements does not match a rotational orientation of a fourth nanostructure element of the repeating set of nanostructure elements.

9. The polarization sensor of claim 8, wherein:
a width of the third nanostructure element does not match the width of the fourth nanostructure element, or
a length of the third nanostructure element does not match the length of the fourth nanostructure element.

10. The polarization sensor of claim 8, wherein:
a width of a fifth nanostructure element of the metastructure matches the width of a sixth nanostructure element of the metastructure, and
a length of the fifth nanostructure element of the metastructure matches the length of the sixth nanostructure element of the metastructure.

11. The polarization sensor of claim 1, wherein light passes through at least one of a global lens, a microlens, or an anti-reflective layer of the polarization sensor to reach the metastructure.

12. The polarization sensor of claim 1, wherein the polarization sensor comprises a capping layer between the metastructure and the wire grid array, the wire grid array being adjacent to the photodetector, and the capping layer comprising a refractive index equal to or less than 3.

13. The polarization sensor of claim 1, wherein the first polarization of light or the second polarization of light include a horizontal polarization, a vertical polarization, a diagonal polarization, an anti-diagonal polarization, a right-handed circular polarization, or a left-handed circular polarization.

14. The polarization sensor of claim 1, wherein the metastructure comprises at least one layer of nanostructure elements, at least one of the layers comprising a relatively high index dielectric.

15. The polarization sensor of claim 1, wherein the wire grid array comprises at least one of an array of metal wires and a substrate.

16. A system comprising:
at least one polarization sensor, the at least one polarization sensor comprising:
a metastructure comprising two or more nanostructure patterns that are configured to route polarization states of light towards a photodetector of the polarization sensor, the two or more nanostructure patterns comprising:
a first nanostructure pattern configured to route a first polarization of light to a first wire grid of a wire grid array, and
a second nanostructure pattern configured to route a second polarization of light different from the first polarization of light to a second wire grid of the wire grid array; and
the wire grid array configured to filter the first polarization of light and the second polarization of light to sensor pixels of the photodetector.

17. The system of claim 16, wherein:
the first wire grid of the wire grid array is configured to allow the first polarization of light of a first wavelength to pass through to a first sensor pixels of the photodetector and reflect the second polarization of light away from the first sensor pixels, and
the second wire grid of the wire grid array is configured to allow the second polarization of light of the first wavelength to pass through to a second sensor pixels of the photodetector and reflect the first polarization of light away from the second sensor pixels of the photodetector.

18. The system of claim 16, wherein:
the first nanostructure pattern is configured to route a first wavelength of light to the first wire grid of the wire grid array, and
the second nanostructure pattern is configured to route a second wavelength of light different from the first wavelength of light to the second wire grid of the wire grid array.

19. A method of routing polarization states of light towards a photodetector of a polarization sensor, the method comprising:
routing, via a first nanostructure pattern of a metastructure, a first polarization of light to a first wire grid of a wire grid array;
routing, via a second nanostructure pattern of the metastructure, a second polarization of light different from the first polarization of light to a second wire grid of the wire grid array; and
filtering, via the wire grid array, the first polarization of light and the second polarization of light to sensor pixels of the photodetector.

20. The method of claim 19, wherein:
the first wire grid of the wire grid array is configured to allow the first polarization of light of a first wavelength to pass through to a first sensor pixels of the photodetector and reflect the second polarization of light away from the first sensor pixels, and
the second wire grid of the wire grid array is configured to allow the second polarization of light of the first wavelength to pass through to a second sensor pixels of the photodetector and reflect the first polarization of light away from the second sensor pixels of the photodetector.
